(19) United States
(12) Patent Application Publication
(10) Pub. No.: US 2022/0216665 A1
(43) Pub. Date: Jul. 7, 2022

(54) LASER PROCESSING METHOD OF PRINTED CIRCUIT BOARD AND LASER PROCESSING MACHINE FOR PRINTED CIRCUIT BOARD

(71) Applicant: OFUNA ENTERPRISE Japan Co., Ltd., Tokyo (JP)

(72) Inventors: Kunio ARAI, Tokyo (JP); Yasuhiko KANAYA, Tokyo (JP); Izumi HATA, Tokyo (JP); Yasuhiko KITA, Tokyo (JP); Hidenori TATEISHI, Tokyo (JP); Kazuhisa ISHII, Tokyo (JP)

(21) Appl. No.: 17/564,513

(22) Filed: Dec. 29, 2021

(30) Foreign Application Priority Data
Jan. 2, 2021 (JP) 2021-017801

(51) Int. Cl. H01S 3/104; H05K 3/00; H01S 3/00; H01S 3/11; B23K 26/0622; B23K 26/38

(52) U.S. Cl. CPC H01S 3/104; H05K 3/0026; H01S 3/0071; H01S 3/2232; B23K 26/0622; B23K 26/38; H01S 3/11

(57) ABSTRACT

A laser processing method includes providing a unit configured to obtain time t0 from a time when the high-frequency pulse RF output is turned on to a time when the laser is actually output in advance and change a traveling direction of the laser in an optical path of the laser, irradiating the workpiece with all the lasers while the high-frequency pulse RF output is turned on, and removing at least a part of the laser from the workpiece simultaneous with turning off the high-frequency pulse RF output.

### BACKGROUND OF THE INVENTION

### Field of the Invention

The present invention relates to a laser processing method of a printed circuit board and a laser processing machine for a printed circuit board in which a blind hole (hereinafter, simply referred to as a hole or BH) which connects a copper layer on a front surface and a copper layer on an inner-layer at a desired position of a build-up type printed circuit board or a through-hole (hereinafter, referred to as TH) which connects a copper layer on a front surface and a copper layer on a back surface is formed by processing a double-sided substrate from the front and back, respectively.

### Description of the Related Art

A build-up type printed circuit board includes a copper layer as a conductor and an insulating layer (hereinafter, simply referred to as an “insulating layer”.) made of a resin containing glass fiber or a filler. As the copper layer, not only a copper layer having a thickness of 5 to 12 μm that has been subjected to a surface treatment (referred to as black oxide treatment, brown treatment, or the like) for the purpose of enhancing laser absorption, but also a copper layer having a thickness of 1.5 to 2 μm of a glossy surface that has not been subjected to a surface treatment has been used. In addition, a thickness of the insulating layer is 20 to 200 μm. In addition, in the case of processing a hole with a carbon dioxide gas laser (CO2 Laser), a hole of 40 to 120 μm is processed for interlayer connection in order to connect a copper layer on a front surface and a copper layer on an inner-layer by plating, a through-hole of 80 to 100 μm having an hourglass-shaped cross section that connects a front surface and a back surface of a board is processed in order to connect a front surface circuit and a back surface circuit of the board by the plating, and a hole of 120 to 250 μm used as a reference hole in the case of forming a circuit pattern are each processed. Then, the laser processing requires a processing result that facilitates a plating step which is a post-step.

Next, a configuration of a laser processing machine in the related art will be described.

FIG. 9 is an overall view of a laser processing machine in the prior art.

A laser oscillator 1 outputs a pulsed linearly polarized laser 2.

A beam diameter adjustment device 3 disposed between the laser oscillator 1 and a plate 6 is a device for adjusting an energy density of a laser 2, and adjusts the energy density of the laser 2 by changing an outer diameter of the laser 2 output from the laser oscillator 1. That is, the energy of the laser 2 before and after the beam diameter adjustment device 3 does not change. Therefore, since the laser 2 emitted from the beam diameter adjustment device 3 can be regarded as the laser 2 output from the laser oscillator 1, hereinafter, the laser oscillator 1 and the beam diameter adjustment device 3 are collectively referred to as a laser output device 1A. Note that the beam diameter adjustment device 3 may not be used.

A polarization conversion device 5 is disposed between the beam diameter adjustment device 3 and the plate 6. The polarization conversion device 5 converts the linearly polarized laser 2 into a circularly polarized laser 4. Note that the polarization conversion device 5 includes a reflected beam blocking mechanism (Details are omitted.) that blocks a laser 4 reflected by a processing unit during processing, and has a function of preventing damage to the laser oscillator 1 by the laser 4 reflected by the processing unit.

The plate 6 disposed between the polarization conversion device 5 and a galvano mirror 7a is made of a material (for example, copper) that does not transmit the laser 4, and a plurality of apertures (window, in this case, a circular through-hole) 8 are selectively formed at a predetermined position.

The plate 6 is driven by a drive device (not illustrated) to position an axis of the selected aperture 8 coaxially with an axis of the laser 4. The galvano device 7 includes a pair of galvano mirrors 7a and 7b, is rotatable around a rotation axis as indicated by arrows in FIG. 9, and can position a reflecting surface at an arbitrary angle. An fθ lens (condenser lens) 9 is held by a processing head (not illustrated). The galvano mirrors 7a and 7b and the fθ lens 9 constitute an optical axis positioning device that positions the optical axis of the laser 4 at a desired position on a printed circuit board 10, and a scan area (that is, processing area) 11 determined by rotation angles of the galvano mirrors 7a and 7b and a diameter of the fθ lens 9 is about 50 mm×50 mm. The printed circuit board 10 including a copper layer as a workpiece and an insulating layer is fixed to an X-Y table 12. A control device 20 controls the laser oscillator 1, the beam diameter adjustment device 3, the drive device of the plate 6, the galvano mirrors 7a and 7b, and the X-Y table 12 according to an input control program.

Then, in the case of processing a hole, after the X-Y table 12 is moved to cause the fθ lens 9 to face a designated processed region 11, first, holes (holes opened on a copper layer 10c is referred to as a window.) are processed on all the copper layers in the processed region 11 by one-time beam irradiation (that is, irradiation of one pulse), and then, the insulating layer under the window is processed by one time to a plurality of times of pulse irradiation to complete the holes in the processed region 11. Note that, upon processing an insulating layer 10z, in a case where one hole is irradiated with a pulse a plurality of times, the hole having the same diameter in the processed region 11 is processed by a so-called cycle processing method.

In addition, in the case of processing the through-hole, all the holes are processed halfway from one side of the printed circuit board 10, then the printed circuit board 10 is flipped, and all the holes are processed from the other side to complete the through-hole having the hourglass-shaped cross section.

Next, a characteristic of a case where the laser is a carbon dioxide laser will be described.

FIG. 10 is a diagram for explaining the output of the laser oscillator 1 disclosed in JP 2020-108904 A, and an upper stage is a high-frequency pulse RF output activated by a control signal of the laser oscillator 1. In addition, a lower stage indicates an output waveform of one pulse of the laser 2, a vertical axis represents an output level, and a horizontal axis represents time. In a case where the laser oscillator 1 is activated (time T0), a high-frequency pulse RF is applied to a laser medium inside the laser oscillator 1, and energy charging is started. In a case where the energy is saturated, the laser 2 is output (time T1). The output of the laser 2 rapidly increases immediately after the oscillation (time Tj), and then decreases once (time Td). Thereafter, the output increases, and then gradually decreases (note that FIG. 10 is a diagram during the increase in the output.). Then, even if the laser oscillator 1 is stopped, that is, the application of the high-frequency pulse RF is stopped (time T2), the energy is continuously output while being attenuated, and becomes 0 at time T3. Then, a pulse energy Ep of one pulse is a total energy amount during a period from the time T1 to the time T3 at which the output level becomes 0.

Hereinafter, the output level at the time Tj is referred to as a first peak output WP1, and the output level at which the output after the output decreases once (time Td) is maximized is referred to as a second peak output WP2. Note that, in FIG. 10, output is increasing, the second peak output WP2 is not displayed.

In addition, there are various output modes such as those (JP 2000-263271 A) in which not only an output of a laser output from a laser oscillator gradually increases after a laser oscillation starts, then decreases once, increases again, reaches an almost constant value, and then disappears, as in the case of the above laser oscillator, but also the output of the laser gradually increases after the oscillation starts (a ratio of the increasing output may be slow or fast), reaches an almost constant value, and then disappears.

According to the technique of JP 2020-108904 A, a printed circuit board 7 can be processed in which a thickness of a copper layer on a front surface that has been subjected to a surface treatment is 7 μm, a thickness of a copper layer on the printed circuit board 7 with an insulating layer having a thickness of 60 μm or an untreated front surface is 1.5 μm, and a thickness of the insulating layer is 40 μm, but diameters of the holes that can be processed are unclear, and in practice, the reliability of processing was improved by increasing the number of holes to be processed (for example, 20% more).

In recent years, in order to stabilize the transmission signal of the multilayer printed circuit board, it is required to shorten the wiring length, and to enable the following processing which is difficult to process with the conventional technique. In addition, further improvement in processing efficiency is also required.

That is,

(1) Processing BH having a diameter of 60 μm or less on a build-up board including a glossy surface copper layer having a plate thickness of 2 μm built up by sandwiching an insulating layer having a thickness of 60 μm or less in a surface-roughened inner copper layer (copper layer on a hole bottom) having a plate thickness of 12 μm or less.

(2) Processing TH having a hole diameter of 60 μm or less on a double-sided substrate in which an insulating layer having a thickness of 60 μm or less is sandwiched, and copper layers on a front surface and a back surface have a glossy surface having a plate thickness of 1.5 to 2 μm.

The present invention provides a laser processing method of a printed circuit board and a laser processing machine for a printed circuit board capable of shortening a wiring length of a printed circuit board and efficiently processing a hole with excellent quality.

### SUMMARY OF THE INVENTION

According to a first aspect of the present invention, a laser processing method of a printed circuit board that processes a workpiece by irradiating the workpiece with a laser output from a laser output device whose output is controlled by a high-frequency pulse RF output, the method includes providing a unit configured to obtain time t0 from a time when the high-frequency pulse RF output is turned on to a time when the laser is actually output in advance and change a traveling direction of the laser in an optical path of the laser, irradiating the workpiece with all the lasers while the high-frequency pulse RF output is turned on, and removing at least a part of the laser from the workpiece simultaneous with turning off the high-frequency pulse RF output.

According to a second aspect of the present invention, a laser processing method of a printed circuit board that processes a workpiece by irradiating the workpiece with a laser output from a laser output device whose output is controlled by a high-frequency pulse RF output, the method includes providing a period setting unit configured to obtain period t0 from a time when the high-frequency pulse RF output is turned on to a time when the laser is actually output in advance and set a second period t10 following the period t0 and a third period t1 following the period t10, and a unit configured to change a traveling direction of the laser in an optical path of the laser, turning on the high-frequency pulse RF output during the periods t0, t10, and t1, removing at least a part of the laser from the workpiece during the periods t0 and t10, irradiating the workpiece with all the lasers during the period t1, and removing at least a part of the laser from the workpiece simultaneous with turning off the high-frequency pulse RF output in a case where the period t1 elapses.

According to a third aspect of the present invention, a laser processing machine for a printed circuit board that includes a laser output device whose output is controlled by a high-frequency pulse RF output and processes a workpiece by irradiating the workpiece with a laser output from the laser output device, the laser processing machine includes a course changing device configured to obtain time t0 from a time when the high-frequency pulse RF output is turned on to a time when the laser is actually output in advance and change a traveling direction of the laser between the laser output device and the workpiece. The course changing device is configured to irradiate the workpiece with all the lasers while the laser output device is turned on, and remove at least a part of the laser from the workpiece while the high-frequency pulse RF output is turned off.

According to a fourth aspect of the present invention, a laser processing machine for a printed circuit board that includes a laser output device whose output is controlled by a high-frequency pulse RF output and processes a workpiece by irradiating the workpiece with a laser output from the laser output device, the laser processing machine includes a unit configured to obtain time t0 from a time when the high-frequency pulse RF output is turned on to a time when the laser is actually output in advance and set a second period t10 following the period t0 and a third period t1 following the period t10, and a course changing device configured to change the traveling direction of the laser. The course changing device is disposed between the laser output device and the workpiece. The high-frequency pulse RF output is turned on during the periods t0, t10, and t1. At least a part of the laser is removed from the workpiece during the periods t0 and t10. The workpiece is irradiated with all the lasers during the period t1. At least a part of the laser is removed from the workpiece simultaneous with turning off the high-frequency pulse RF output in a case where the period t1 elapses.

Further features of the present invention will become apparent from the following description of exemplary embodiments with reference to the attached drawings.

### BRIEF DESCRIPTION OF THE DRAWINGS

FIG. 1 is a configuration diagram of a laser processing machine according to the present invention.

FIGS. 2A and 2B are operation explanatory diagrams schematically illustrating an operation of the electro-optics modulator (EOM).

FIG. 3 is a diagram illustrating a pulse waveform during processing in the present invention.

FIG. 4 is a diagram illustrating a pulse waveform during processing in the present invention.

FIG. 5 is a diagram illustrating a pulse waveform during processing in the present invention.

FIGS. 6A and 6B are operation explanatory diagrams schematically illustrating an operation of an acousto-optics modulator (AOM).

FIG. 7 is a diagram illustrating a pulse waveform during processing in the present invention.

FIG. 8 is a diagram illustrating a pulse waveform during processing in the present invention.

FIG. 9 is a configuration diagram of a laser processing machine in the related art.

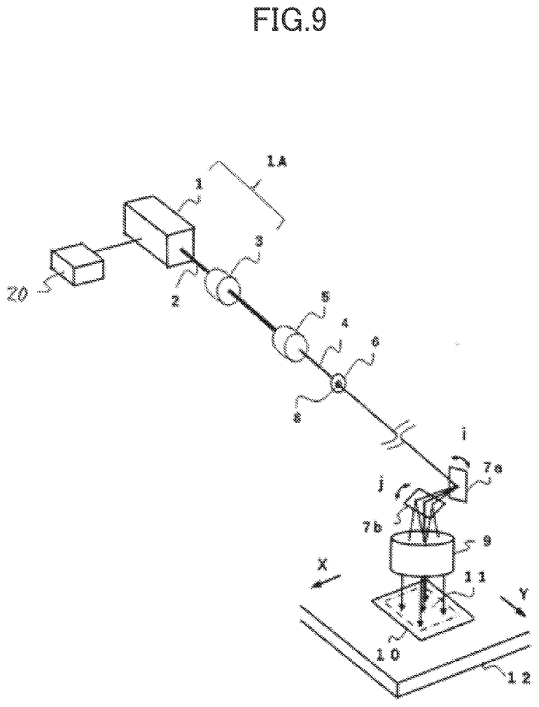

FIG. 10 is a graph explaining an output of a laser oscillator 1.

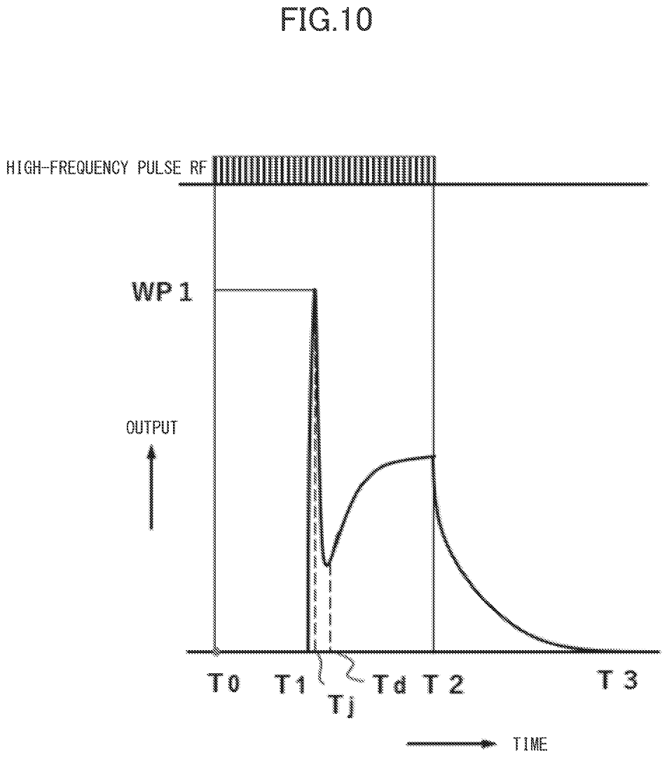

FIGS. 11A to 11F are a diagrams for explaining a relationship between an application period of a high-frequency pulse RF and laser output.

### DESCRIPTION OF THE EMBODIMENTS

The present inventor has referred to conventional processing data and performed processing under various conditions. As a result, in a case where holes having a diameter of 60 μm or less are processed in a workpiece in which at least one of a copper layer and an insulating layer on a front surface is thin,

(A) In a case where a pulse period is lengthened at the time of processing the copper layer, heat at the time of processing is diffused, and the insulating layer corresponding to a window and the insulating layer around the window are damaged, and thus gouging gets bigger. Therefore, in order to reduce the gouging under the copper layer,

(1) Processing the copper layer in as short a time as possible.

(2) In order to reduce variations in processing results, accurately controlling a processing time.

Furthermore,

(3) In order to prevent an increase in burnout of an insulating layer, suppressing the energy supplied to the processed portion after the window is formed.

In a case where the laser oscillator is a carbon dioxide laser oscillator, the laser is output in the following order. That is,

(1) A high-frequency pulse RF is applied.

(2) N₂ gas molecules in the laser medium are excited by the applied high-frequency pulse RF, and an energy level increases.

(3) In a case where the energy level of the N₂ gas molecules increases, the energy of the N₂ gas molecules is transitioned to CO₂ gas molecules, and an energy level of the CO₂ gas molecules increases.

(4) In a case where the energy level of the CO₂ gas increases and reaches saturation, that is, an flipped distribution state, a pulse is output, that is, a laser is output in a case where returning to a ground state.

Then, during the high-frequency pulse RF application, the N₂ gas molecules are re-excited thereby not to return to the ground state, and the pulse period continues.

(5) In a case where the laser is output, since the energy accumulated in the N₂ gas molecules and the CO₂ gas molecules is output at a time during a time (from time T0 to time T1) from a time when the high-frequency pulse RF is applied to a time where the laser is output, a relatively high initial output WP1 is output. Thereafter, the output decreases once, but rises again because the excitation continues.

However, in the case of JP 2020-108904 A, there is a variation of ±0.3 μs during a time from a time when the high-frequency pulse RF is applied to the laser medium to a time when a stable pulse is output. However, in order to finely control the pulse output period, it is necessary to minimize the variation in the laser output start time.

Therefore, as a first stage, the relationship between the high-frequency pulse RF application period and the pulse generation time was examined.

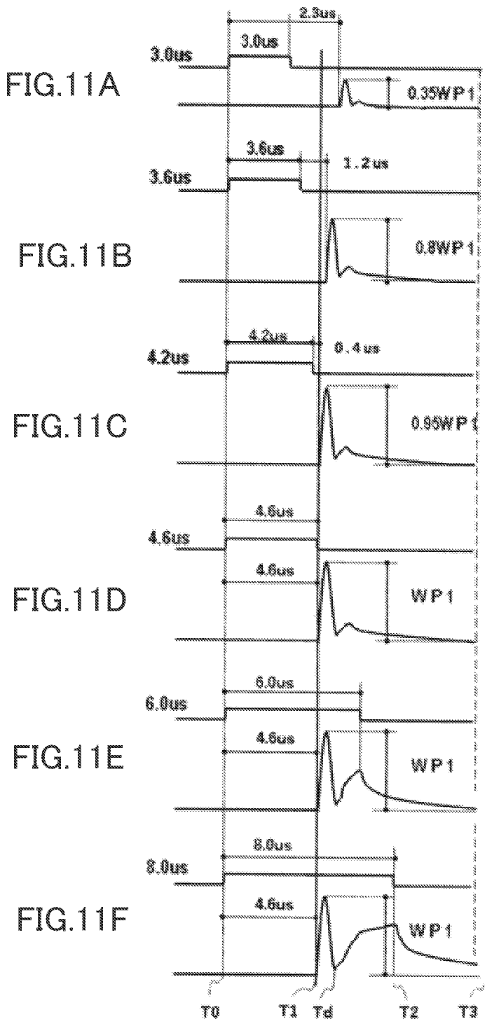

FIGS. 11A to 11F are diagrams for explaining the relationship between the application period of the high-frequency pulse RF and the laser output, and the upper stage shows turn on/off of the high-frequency pulse RF and the lower stage shows the laser output. In addition, a horizontal axis represents a time, and T0 represents time 0.

As illustrated in FIGS. 11A to 11F, in a case where the high-frequency pulse RF was applied for 3.0 μs, the laser was output at 2.3 μs after the application of the high-frequency pulse RF was stopped, and the peak output was 0.35 WP1. (However, WP1 is a peak value in a case where the high-frequency pulse RF is continuously applied.)

In addition, as illustrated in FIG. 11B, in a case where the high-frequency pulse RF was applied for 3.6 μs, the laser was output at 1.2 μs after the application of the high-frequency pulse RF is stopped, and the peak output was 0.8 WP1.

In addition, as illustrated in FIG. 11C, in a case where the high-frequency pulse RF was applied for 4.2 μs, the laser was output at 0.4 μs after the application of the high-frequency pulse RF is stopped, and the peak output was 0.95 WP1.

In addition, as illustrated in FIG. 11D, in a case where the high-frequency pulse RF was applied for 4.6 μs, the laser was output at the same time the application of the high-frequency pulse RF ends, and the peak output was WP1.

In addition, as illustrated in FIG. 11E, in a case where the high-frequency pulse RF was continuously applied for 6 μs, and furthermore, as illustrated in FIG. 11F, in a case where the high-frequency pulse RF was continuously applied for 8 μs, the laser was output at 4.6 μs and the peak output was WP1 as in the case of FIG. 11D in both cases.

From the above results, it was confirmed that in the case of the laser oscillator used for the test, the time after 4.6 μs from the time T0 can be set as the laser output time T1. As a result, the variation in the laser output start time can be set to zero. Furthermore, in the above test, it has been found that the time Td hardly varies.

Next, as a second stage, in considering a specific means of reducing damage to an insulator, it was assumed that the damage to the insulator spreads after the completion of the copper layer processing, that is, after the formation of the window.

Then,

(a) Even if the high-frequency pulse RF is stopped at the same time (time T2) as the hole, that is, the window is completed in the copper layer, the laser is output until the energy remaining in the laser oscillator 1 disappears,

(b) The energy remaining in the laser oscillator 1 corresponds to the laser output at the time (time T2) when the high-frequency pulse RF is stopped, and the smaller the output at that time, the smaller the energy becomes.

(c) Time Td, which is a valley of the output in a case where the output transitions from a first peak to a second peak, is about 0.5 μs, and from the viewpoint of hardly changing, attention is paid to the time Td.

Then, the energy Ewc for drilling a hole of 40 μm in the copper layer having a thickness of 2 μm was calculated to be 1.3 to 1.8 mJ based on the conventional processing data. Note that an object to be processed at the time of the calculation, which has specifications of a window diameter of 40 μm and a hole having a diameter of 40 μm and a depth of 20 to 30 μm is formed in the insulating layer simultaneously with the window processing. In addition, it was also considered that the glossy copper layer is difficult to absorb the laser, and the energy diffused around the processed portion is large due to a high thermal conductivity of copper. Furthermore, the value of the peak output WP1 in a case where the energy Ewc or more is obtained in a case where the pulse irradiation time is set to 0.5 μs is obtained by calculation, and it is considered that the value of WP1 may be 3 kW or more.

As a result of confirming the characteristics of the laser oscillator 1 used in the test,

(1) In a case where the excitation is performed by applying the high RF output, the first output level WP1 and the second output level WP2 increase at a substantially constant ratio. Then, WP1 is about 3 KW, which is about twice as large as WP2.

(2) In a case where a gas pressure increases and the excitation is performed at a relatively high RF, a relatively large output can be obtained with a quick rise in output.

(3) In a case where a high high-frequency pulse RF is applied in a state where an electrode gap is narrowed and the gas pressure increases by increasing the amount of laser medium in a unit space, a relatively large output can be obtained with a quick rise in output.

From the above results, it was confirmed that the value of the first peak output can be set to be the output WP1 in advance as the output characteristic of the laser oscillator 1.

Note that it was also confirmed that the output characteristics of the laser oscillator 1 were slightly different for each laser oscillator 1, but the characteristics set once hardly changed due to aging.

Then, the results of the first stage and the second stage were applied to the processing, and it was confirmed that a window having a diameter of 60 μm can be processed in the copper layer of 2 μm. However, due to the variations in the components of the insulating layer, the damage to the insulator at the lower portion of the window and around the window sometimes increased.

In addition, in a case where the thickness of the insulating layer was thin, a tip of the opened hole sometimes reached the lower copper layer, and in some cases, a hole whose diameter hardly changed was formed up to the copper layer on the inner-layer.

In the case of the hole (BH), a hole having a conical cross section in which the diameter of the hole on the bottom surface is 80% of the diameter of the window is ideal as the hole connecting the copper layer on the front surface and the copper layer on the bottom surface.

In addition, the case of the through-hole (TH), in order to make the diameter of the hole processed from the back surface the same as that on the front surface side, it is necessary to use an expansion force in a case where the insulator vaporized under the copper layer during the processing vaporizes. For this reason, it is necessary to leave a certain degree of insulating layer above the copper layer on the inner-layer. In addition, the cross-sectional shape of the through-hole is preferably an hourglass shape.

As described above, it was assumed that the increase in damage to the insulator and the increase in the hole diameter of the insulator during window processing are due to the pulse energy supplied to the processed portion after the high-frequency pulse RF is stopped.

Therefore, as a third stage, the pulse energy supplied to the processing unit after the high-frequency pulse RF is stopped is attenuated, and an electro-optics modulator (EOM) is first adopted as a means for attenuating the pulse energy.

Then, as the result that the EOM is operated at the timing when high-frequency pulse RF is stopped to guide most (almost 100%) of the pulse energy supplied after the high-frequency pulse RF is stopped to portions other than the processed portion, it has been confirmed that the damage to the insulator and the enlargement of the hole diameter can be reduced.

Hereinafter, a specific description will be given with reference to the drawings.

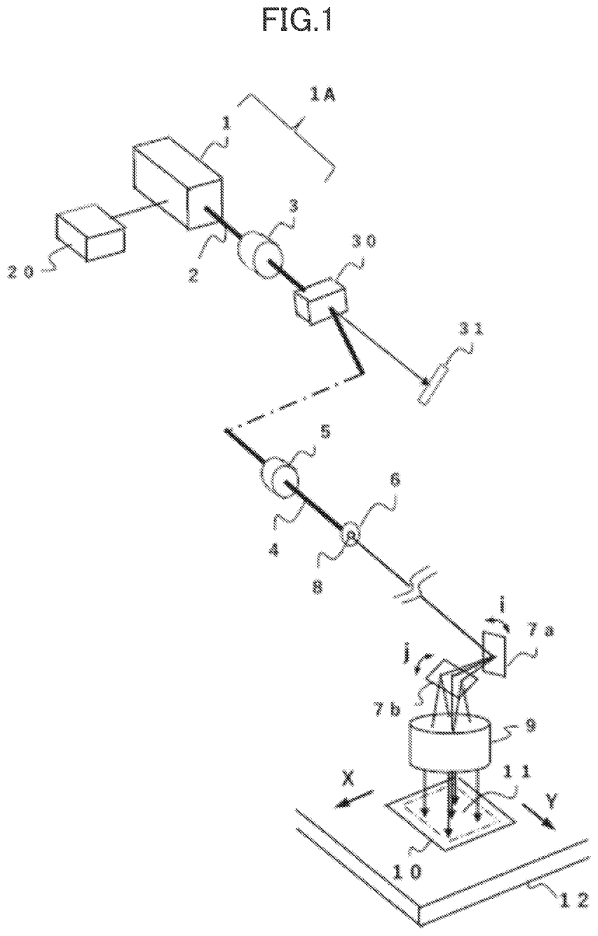

FIG. 1 is a configuration diagram of a laser processing machine (laser processing devise) according to the present invention, and the same components or components having the same function as those used in the related art are designated by the same reference numerals, and duplicate description thereof will be omitted.

In FIG. 1, a course changing device 30 that changes a traveling direction of a laser is disposed between a beam diameter adjustment device 3 and a polarization conversion device 5. In this embodiment, since the electro-optics modulator (EOM) is adopted as the course changing device 30, the course changing device 30 is hereinafter referred to as an electro-optics modulator (EOM) 30. A control device 20 controls turn on/off of the EOM 30 in addition to controlling a laser oscillator 1, a beam diameter adjustment device 3, a drive device of a plate 5, galvano mirrors 7a and 7b, and an X-Y table 12 according to an input control program.

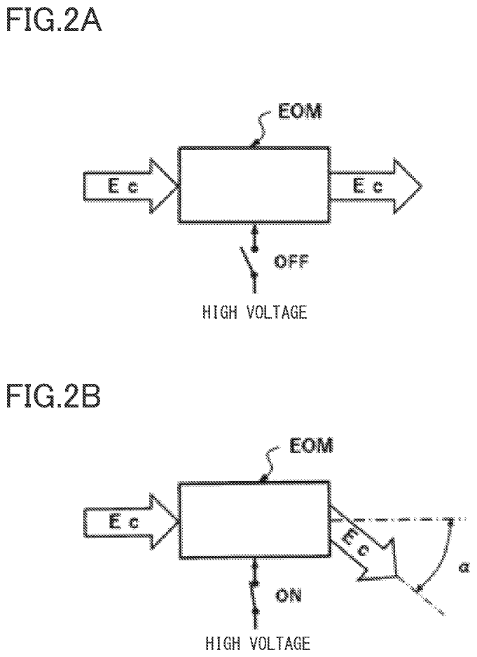

FIGS. 2A and 2B are operation explanatory diagrams schematically illustrating the operation of the electro-optics modulator (EOM) 30.

As illustrated in FIG. 2A, in a case where a high voltage is not applied to the electro-optics modulator (EOM) 30 (that is, in a case where the EOM 30 is turned off), the laser 2 having an output Ec incident on the EOM 30 travels straight inside the EOM 30 and is emitted as the output Ec laser 2 coaxial with the incident beam.

On the other hand, as illustrated in FIG. 2B, in a case where a high voltage is applied to the electro-optics modulator (EOM) 30 (that is, in a case where the EOM 30 is turned on), the laser 2 with the incident output Ec is reflected inside the EOM 30 (reflectance is almost 100%. In addition, the operation time is 0.1 μs or less) and is emitted as the laser 2 with the output Ec at an angle α with respect to the incident direction.

The electro-optics modulator (EOM) 30 is disposed between the beam diameter adjustment device 3 and the polarization conversion device 5 such that the emitted beam emitted in a case where the electro-optics modulator (EOM) 30 is turned on is incident on the galvano mirror 7a. In addition, in a case where the electro-optics modulator (EOM) 30 is turned off, the laser 2 emitted is incident on a beam damper 31 and converted into heat.

Hereinafter, a specific operation will be described.

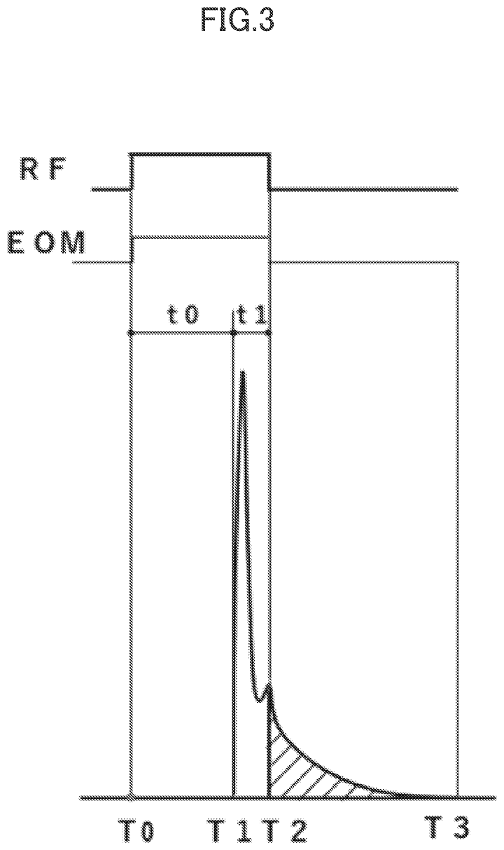

(A) FIG. 3 illustrates a pulse waveform in a case where a copper layer on a front surface is a glossy copper layer having a thickness of 2 μm, and a window having a diameter of 40 μm is processed on a printed circuit board 10 having a thickness of an insulating layer of 40 to 60 μm, and illustrates both the turn on/off of the EOM 30 and the turn on/off of a high-frequency pulse RF. In addition, a vertical axis represents an output level, and a horizontal axis represents a time.

The laser 2 is generated at time T1 when period t0 has elapsed since the high-frequency pulse RF is turned on (time T0) in a state where the EOM 30 is turned on. Then, the EOM 30 and the high-frequency pulse RF are turned off at time T2 when the period t1 has elapsed from time T1. As illustrated in FIG. 3, the laser output increases from time T1 to time Tj, decreases from time Tj to time Td, and increases again after time Td. Then, at time T2, the high-frequency pulse RF is turned off and the EOM 30 is turned off. Since the EOM 30 is turned on from the time T0 to the time T2, all the lasers 2 output from the laser output device 1A are supplied to the printed circuit board 10 as a workpiece. In addition, during a period from time T2 when the window is completed to time T3 when the output is 0, all the lasers 2 output from the laser output device 1A are incident on the beam damper 31. That is, as indicated by hatching in FIG. 3, since the energy of the laser 2 output from the laser output device 1A after the time T2 is not supplied to the insulating layer, it is possible to prevent damage to the insulating layer under the window and around the window. Note that the energy supplied from the time T1 to the time T2 is 1.3 to 1.8 mJ.

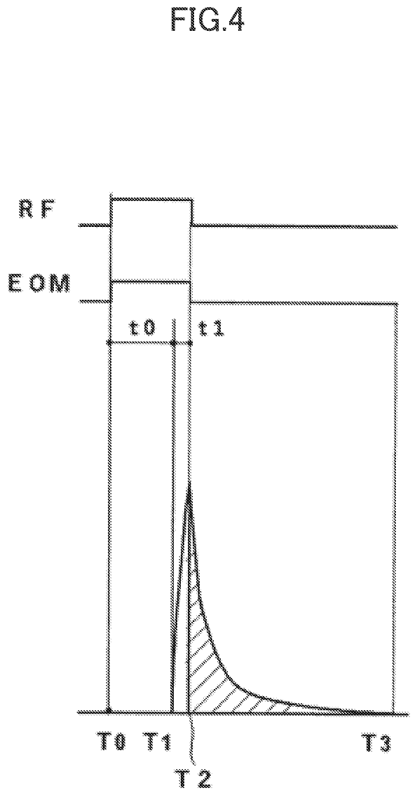

(B) FIG. 4 illustrates a pulse waveform in a case where a copper layer on a front surface is a glossy copper layer having a thickness of 2 μm, and a window having a diameter of 40 μm is processed on a printed circuit board 10 having a thickness of an insulating layer of 40 to 60 μm, and illustrates both the turn on/off of the EOM 30 and the turn on/off of a high-frequency pulse RF. In addition, a vertical axis represents an output level, and a horizontal axis represents a time.

The laser 2 is generated at time T1 when the period t0 has elapsed since the high-frequency pulse RF is turned on (time T0) in a state where the EOM 30 is turned on. Then, the EOM 30 and the high-frequency pulse RF are turned off at time T2 when the period t1 has elapsed from time T1. As illustrated in FIG. 4, the laser output increases from the time T1 to the time T2. Then, at time T2, the high-frequency pulse RF is turned off and the EOM 30 is turned off. Since the EOM 30 is turned on from the time T0 to the time T2, all the lasers 2 output from the laser output device 1A are supplied to the printed circuit board 10 as a workpiece. In addition, after the time T2 when the window is completed, all the lasers 2 output from the laser output device 1A are incident on the beam damper 31. That is, as indicated by hatching FIG. 4, the energy of the laser 2 output from the laser output device 1A is not supplied to the insulating layer during the period from the time T2 to the time T3 when the output becomes 0. Therefore, the damage to the insulating layer at the lower portion of the window and around the window can be prevented. Note that the energy supplied from the time T1 to the time T2 is about 1.3 to 1.8 mJ.

However, in a case of processing a hole having a window diameter of 80 μm or more, there is a case where variations in hole quality can be reduced by performing processing using a laser 4 having a substantially stable output.

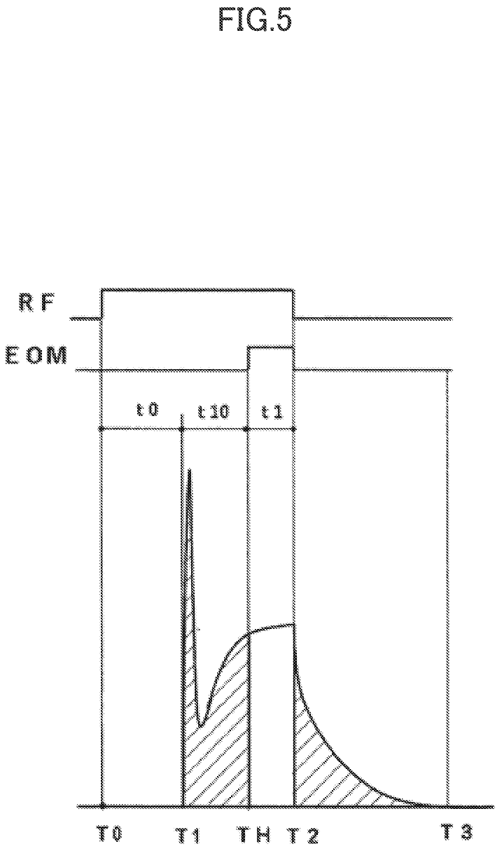

(C) FIG. 5 illustrates a pulse waveform in a case where a copper layer on a front surface is a glossy copper layer having a thickness of 7 μm or more, and a window having a diameter of 60 μm or more is processed on a printed circuit board 10 having a thickness of an insulating layer of 60 μm or more, and illustrates the turn on/off of the EOM 30 and the turn on/off of a high-frequency pulse RF. In addition, a vertical axis represents an output level, and a horizontal axis represents a time.

The high-frequency pulse RF is turned on (time T0) in a state where the EOM 30 is turned off. Then, the EOM 30 continues to be in the turn off state from the time T1 to time TH when period t10 has further elapsed. Then, the EOM 30 is turned on at the time TH, and the EOM 30 is again turned off at the time T2 when period t12 elapses from the time TH, and the turn off state is continued until time T3 is exceeded. As a result, the laser 2 is supplied to the printed circuit board 10 as a workpiece only during the period t1 from the time TH to the time T2, and is not supplied to the printed circuit board 10 during the other periods. As a result, as indicated by hatching in FIG. 5, the energy of the laser 2 output from the laser output device 1A after the time T2 is not supplied to the insulating layer. Therefore, the damage to the insulating layer at the lower portion of the window and around the window can be prevented. Note that, although illustration is omitted, there is an oscillator of a type in which the output of the laser is gradually increased depending on the laser oscillator 1. However, even in such a laser oscillator 1, for example, by supplying the laser 4 to a workpiece for 0.5 μs based on the time point at which the output exceeds 3 kW, it is possible to process a window having a diameter of 60 μm on the printed circuit board 10 having an insulating layer thickness of 40 to 60 μm even in a case where the copper layer on the front surface is the glossy copper layer having a thickness of 2 μm as in the case of (A).

Note that it is needless to say that all the laser outputs are incident on the beam damper 31 from the time T1 to the time TH indicated by hatching in FIG. 5.

Next, a case where the acousto-optic element (AOM) is adopted as the course changing device 30 instead of the electro-optic element EOM will be described. Note that the acousto-optics modulator (AOM) may be arranged at the position of the electro-optics modulator (EOM) 30 in FIG. 1, and thus illustration of the entire view will be omitted.

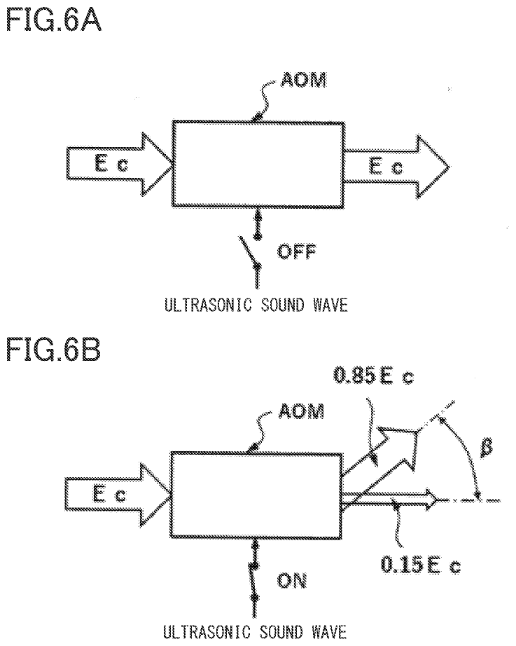

FIGS. 6A and 6B are operation explanatory diagrams schematically illustrating an operation of the acousto-optics modulator (AOM).

As illustrated in FIG. 6A, in a case where no ultrasonic wave is added to the acousto-optics modulator (AOM) (that is, in a case where the acousto-optics modulator (AOM) is turned off), the laser 2 of the output Ec incident on the acousto-optics modulator (AOM) travels straight inside the acousto-optics modulator (AOM), and is emitted as the laser 2 whose output Ec is coaxial with the incident beam.

On the other hand, as illustrated in FIG. 6B, in a case where an ultrasonic wave is added to the acousto-optics modulator (AOM) (that is, in a case where the acousto-optics modulator (AOM) is turned on), first-order diffracted beam having an output of 0.85 Ec (that is, 85% of the output of the incident laser 2) is emitted as an emission beam at an angle β with respect to the incident direction, and zero-order beam having an output of 0.15 Ec (that is, 15% of the output of the incident laser 2) is emitted as the laser 2 coaxial with the incident beam. Note that the operation time of the acousto-optics modulator (AOM), that is, the time required for the ultrasonic wave to pass through the beam is about 1.0 μs.

The acousto-optics modulator (AOM) 30 is disposed between the beam diameter adjustment device 3 and the polarization conversion device 5 so that the zero-order beam is incident on the galvano mirror 7a. In addition, the first-order diffracted beam emitted from the acousto-optic element (AOM) 30 in a case where the acousto-optic element (AOM) 30 is turned on is incident on the beam damper 31 and is converted into heat.

Hereinafter, a specific operation will be described.

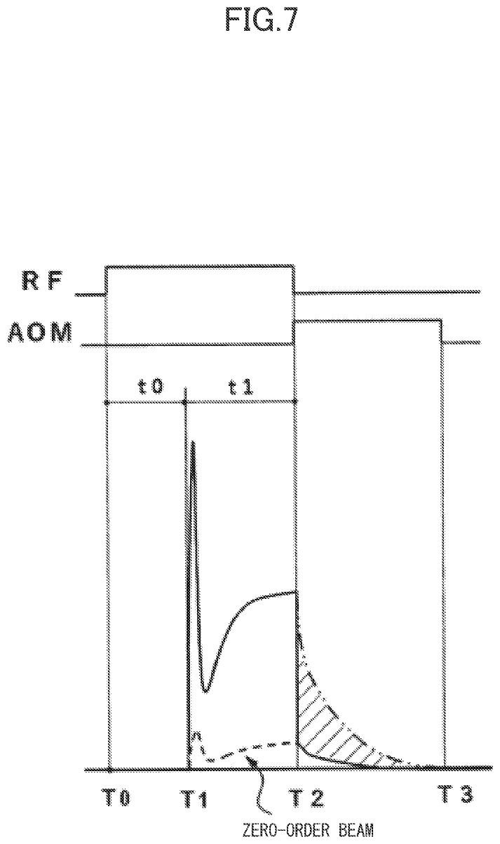

(D) FIG. 7 illustrates a pulse waveform in a case where a copper layer on a front surface is a glossy copper layer having a thickness of 2 μm, and a window having a diameter of 60 μm is processed on a printed circuit board 10 having a thickness of an insulating layer of 40 to 60 μm, and illustrates the turn on/off of the AOM 30 and the turn on/off of a high-frequency pulse RF. In addition, a vertical axis represents an output level, and a horizontal axis represents a time. Note that FIG. 7 corresponds to FIG. 4 described above.

The laser 2 is generated at time T1 when period t0 has elapsed since the high-frequency pulse RF is turned on (time T0) in a state where the AOM 30 is turned on. Then, the AOM 30 is turned on at the same time the high-frequency pulse RF is turned off at the time T2 when the period t1 has elapsed from time T1. As illustrated in FIG. 3, the laser output increases from time T1 to time Tj, decreases from time Tj to time Td, and increases again after time Td. Then, at the time T2, the high-frequency pulse RF is turned off and the AOM 30 is turned on. Since the AOM 30 is turned off from the time T0 to the time T2, all the lasers 2 output from the laser output device 1A are supplied to the printed circuit board 10 as a workpiece. In addition, since the AOM 30 is turned on during the period from the time T2 when the window is completed to the time T3 when the output becomes 0, the first-order diffracted beam of the laser 2 output from the laser output device 1A is incident on the beam damper 31, and the zero-order beam is incident on the printed circuit board 10 as a workpiece. As a result, as indicated by hatching in FIG. 7, 85% of energy of the laser 2 output from the laser output device 1A after the time T2 is not supplied to the insulating layer. Therefore, the damage to the insulating layer at the lower portion of the window and around the window can be reduced to a negligible extent.

Note that the above case (B) can be easily understood from this embodiment, and thus description thereof will be omitted.

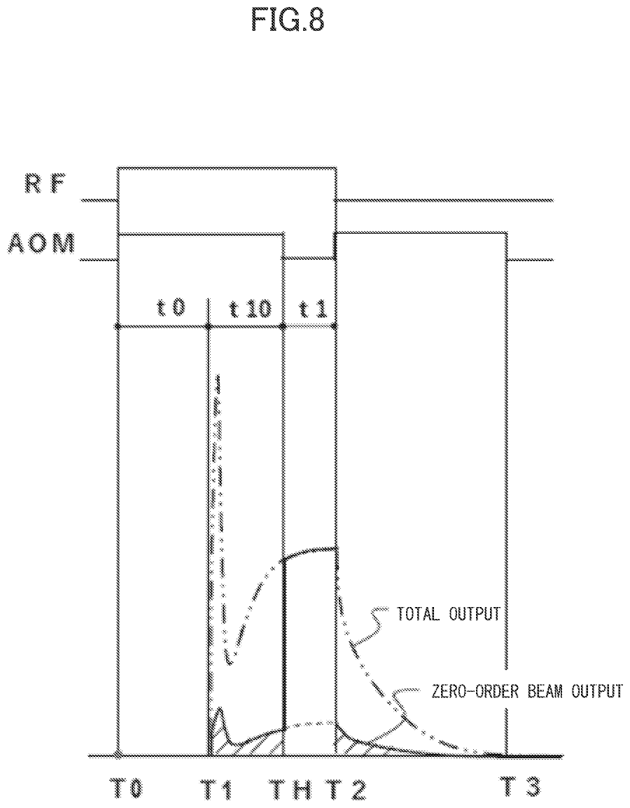

(E) FIG. 8 is an explanatory diagram in a case where the processing described in (C) above is processed using the acousto-optic element (AOM), that is, where a pulse waveform in a case where the copper layer on the front surface is a glossy copper layer having a thickness of 7 μm or more, and a window having a diameter of 80 μm or more is processed on the printed circuit board 10 having a thickness of the insulating layer of 60 μm or more, and illustrates both the turn on/off of the AOM 30 and the turn on/off of the high-frequency pulse RF. In addition, a vertical axis represents an output level, and a horizontal axis represents a time. Note that, in the drawing, a two-dot chain line portion indicates total pulse energy, and a dotted line portion indicates a zero-order beam component.

The high-frequency pulse RF is turned on (time T0) in a state where the AOM 30 is turned on. Then, the AOM 30 continues to be in the turn on state from the time T1 to time TH when period t10 has further elapsed. As a result, during the period from the time T1 to the time TH, only the zero-order beam component of the laser 2 is supplied to the processing unit, and the component of the first-order diffracted beam of the laser 2 is not supplied to the processing unit. Then, the AOM 30 is turned off at the time TH, and the AOM 30 is again turned on at the time T2 when the period t1 elapses from the time TH, and the turn on state is continued until the time T3 is exceeded. As a result, all the lasers 2 are supplied to the processing unit from the time TH to the time T2 (period t1), and only the component of the zero-order beam of the laser 2 is supplied to the processing unit after the time T2. In this case, the zero-order beam of the laser 2 supplied during the period from the time T1 to the time TH preheats the copper layer. In addition, since only the energy of the zero-order beam component of the laser 2 indicated by hatching is supplied to the processing unit after the time T2, it is possible to suppress the damage to the insulating layer at the lower portion of the window and around the window to a negligible extent.

Here, regarding the laser 2, the difference between the present invention and JP 2000-263271 A will be described.

In the case of JP 2000-263271 A, since only the first-order diffracted beam of the laser 2 is used to process the copper layer, only 85% of the output energy of the laser 2 can be used. On the other hand, in the present invention, since all the outputs of the laser 2 are used for copper layer processing, the tolerance of the processing conditions can be increased as compared with JP 2000-263271 A.

Note that, in a case where the EOM is used as the course changing device 30, the operation in a case where the high-frequency pulse RF is turned off is equivalent to the case where the course of the laser is completely blocked. Therefore, instead of the EOM, a shutter capable of blocking the laser path may be adopted as the course changing device 30.

However, in the case of the EOM 30, by applying a high voltage, a phase shifting unit (reflection unit) inside the EOM operates. In the present invention, in paragraph 0024, in a case where a high voltage is applied, the emitted beam is bent by the angle α, but an emission angle can be set to 0 by rotating the phase shift unit by 90° with respect to the case of the present embodiment. However, with such a configuration, the incident beam incident on the EOM 30 without application of a high voltage is emitted at an angle α. Therefore, in a case where the phase shifting unit is rotated by 90° in the case of the present embodiment, it is necessary to cause the laser emitted from the EOM 30 in a state where the high voltage is applied to be incident on the beam damper 31 and cause the laser emitted from the EOM 30 in a state where the high voltage is not applied to be incident on the galvano mirror 7a.

According to the present embodiment, by processing a hole having a diameter of 40 μm or less in a build-up substrate including a glossy surface copper layer having a thickness of 1.5 to 2 μm built up by sandwiching an insulating layer having a thickness of 40 μm or less in a surface-roughened inner copper layer (copper layer at the bottom of the hole) having a plate thickness of 12 μm or less, and furthermore, processing a through hole having a hole diameter of 40 μm or less on a double-sided substrate in which an insulating layer having a thickness of 40 μm or less is sandwiched, and copper layers on a front surface and a back surface have a glossy surface having a plate thickness of 1.5 to 2 μm, it is possible to shorten a wiring length of a printed circuit board and to efficiently process a hole and a through-hole with excellent quality.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-17801, filed Jan. 2, 2021, which is hereby incorporated by reference herein in its entirety.

What is claimed is:

1. A laser processing method of a printed circuit board that processes a workpiece by irradiating the workpiece with a laser output from a laser output device whose output is controlled by a high-frequency pulse RF output, the method comprising:
providing a unit configured to obtain time t0 from a time when the high-frequency pulse RF output is turned on to a time when the laser is actually output in advance and
change a traveling direction of the laser in an optical path of the laser;
irradiating the workpiece with all the lasers while the high-frequency pulse RF output is turned on; and
removing at least a part of the laser from the workpiece simultaneous with turning off the high-frequency pulse RF output.

2. A laser processing method of a printed circuit board that processes a workpiece by irradiating the workpiece with a laser output from a laser output device whose output is controlled by a high-frequency pulse RF output, the method comprising:
providing a period setting unit configured to obtain period t0 from a time when the high-frequency pulse RF output is turned on to a time when the laser is actually output in advance and set a second period t10 following the period t0 and a third period t1 following the period t10, and
a unit configured to change a traveling direction of the laser in an optical path of the laser;
turning on the high-frequency pulse RF output during the periods t0, t10, and t1;
removing at least a part of the laser from the workpiece during the periods t0 and t10;
irradiating the workpiece with all the lasers during the period t1; and
removing at least a part of the laser from the workpiece simultaneous with turning off the high-frequency pulse RF output in a case where the period t1 elapses.

3. A laser processing machine for a printed circuit board that includes a laser output device whose output is controlled by a high-frequency pulse RF output and processes a workpiece by irradiating the workpiece with a laser output from the laser output device, the laser processing machine comprising:
a course changing device configured to obtain time t0 from a time when the high-frequency pulse RF output is turned on to a time when the laser is actually output in advance and
change a traveling direction of the laser between the laser output device and the workpiece,
wherein the course changing device is configured to irradiate the workpiece with all the lasers while the laser output device is turned on, and
remove at least a part of the laser from the workpiece while the high-frequency pulse RF output is turned off.

4. A laser processing machine for a printed circuit board that includes a laser output device whose output is controlled by a high-frequency pulse RF output and processes a workpiece by irradiating the workpiece with a laser output from the laser output device, the laser processing machine comprising:
a unit configured to obtain time t0 from a time when the high-frequency pulse RF output is turned on to a time when the laser is actually output in advance and
set a second period t10 following the period t0 and a third period t1 following the period t10; and
a course changing device configured to change the traveling direction of the laser,
wherein the course changing device is disposed between the laser output device and the workpiece,
the high-frequency pulse RF output is turned on during the periods t0, t10, and t1,
at least a part of the laser is removed from the workpiece during the periods t0 and t10,
the workpiece is irradiated with all the lasers during the period t1, and
at least a part of the laser is removed from the workpiece simultaneous with turning off the high-frequency pulse RF output in a case where the period t1 elapses.

5. The laser processing machine for printed circuit board according to claim 3, wherein
the course changing device is an electro-optics modulator (EOM).

6. The laser processing machine for printed circuit board according to claim 3, wherein
the course changing device is an acousto-optics modulator (AOM).

7. The laser processing machine for printed circuit board according to claim 3, wherein
the course changing device is a shutter.
